(19) United States
(12) Patent Application Publication
(10) Pub. No.: US 2018/0120356 A1
(43) Pub. Date: May 3, 2018

(54) CURRENT MEASURING METHOD AND SYSTEM THEREOF

(71) Applicant: FLEX INSTRUMENTS CO., LTD., New Taipei (TW)

(72) Inventor: Win-Throng Chen, New Taipei (TW)

(21) Appl. No.: 15/341,278

(22) Filed: Nov. 2, 2016

(51) Int. Cl. G01R 15/14; G01R 19/25

(52) U.S. Cl. CPC G01R 15/14; G01R 19/25

(57) ABSTRACT

A current measuring method and system thereof are provided. An adjustable constant current source and a voltage measuring module are connected in parallel to a circuit under test. A test current in different current values is provided at different times to the circuit under test by the adjustable constant current source. A voltage signal when the test current in each of the different values enters the circuit under test is obtained to calculate a voltage change and a current change between the test current in the different values. The impedance of the circuit under test is calculated according to the voltage change and the current change. Power is then provided by a power supply of a circuit in the circuit under test, and the voltage signal of the measured part is obtained. The current is calculated according to the voltage signal and the impedance of the circuit under test.

### FIELD OF THE INVENTION

The present invention relates to a current measuring method and a system thereof, and particularly to a current measuring method and system that measure a current through parallel connection.

### BACKGROUND OF THE INVENTION

In current technologies, to measure the current of a part of a circuit, the part of the circuit to be measured is caused to form open-circuit, and a multimeter is connected in series to the open-circuit part. After the current has been measured, the open-circuit part is then restored. Although the above implementation method achieves the object of measuring the current, pre-operations and post-operations associated are rather tedious that disfavor prompt measuring. Further, by connecting the multimeter in series in the circuit, the intrinsic impedance of the multimeter affects the overall impedance characteristics of the circuit, in a way that the measured result may be distorted.

In addition to the above implementation method, a clamp meter may also be adopted for measuring the current. However, a clamp meter is suitable for only circuits of large currents instead of also being effective for measuring small-current circuits. Further, because a clamp meter needs to be hooked onto a circuit under test, the clamp meter cannot be used to circuits laid out on a circuit board.

### SUMMARY OF THE INVENTION

Therefore, it is a primary object of the present invention to solve issues of conventional current measuring methods.

To achieve the above object, the present invention provides a current measuring method including following steps.

In step 1, a test current input node, a first voltage detection node, a second voltage detection node and a test current output node are sequentially defined according to a current direction of a circuit under test.

In step 2, an adjustable constant current source and a voltage measuring module are connected in parallel to the circuit under test. The impedance of the voltage measuring module is far greater than the impedance of the circuit under test. The adjustable constant current source is electrically connected to the test current input node and the test current output node to form a loop. The voltage measuring module is electrically connected to the first voltage detection node and the second voltage detection node to form a loop.

In step 3, a test current in different current values is provided at different times to the circuit under test by the adjustable constant current source. A voltage signal between the first voltage detection node and the second voltage detection node is measured by the voltage measuring module when the test current in each of the different values enters the circuit under test.

In step 4, a voltage change of the first voltage detection node and the second voltage detection node is measured for the test current in each of the different values and a current between the test current in the different values are calculated, and the impedance of the circuit under test is calculated according to the voltage change and the current change.

In step 5, the adjustable constant current source is disabled, and power is provided by a power supply in a circuit of the circuit under test instead.

In step 6, a voltage signal between the first voltage detection node and the second voltage detection node is obtained by the voltage measuring module, and the current of the circuit under test is calculated according to the voltage signal and the impedance of the circuit under test.

In one embodiment, step 6 further includes a sub-step, in which the circuit under test is caused to be open-circuit between the first voltage detection node and the second voltage detection node, and the voltage signal between the first voltage detection node and the second voltage detection node is obtained and provided to a phase rectification filter circuit to obtain impedance characteristics included in the voltage signal.

In one embodiment, step 6 further includes a sub-step, in which a low-pass filter (LPF) unit or a high-pass filter (HPF) unit is selected to process the voltage signal according to the type of the power supply. More specifically, the voltage signal is processed by the LPF unit when the power supply is a direct-current (DC) source, and is processed by the HPF unit when the power supply is an alternating-current (AC) source.

In addition to the above current measuring method, the present invention further provides a current measuring system. The current measuring system includes two current probes, two voltage sensing probes, an adjustable voltage source, a voltage measuring module, and a computation unit. The two current probes are connected in parallel and in contact with a circuit under test, and a test current input node and a test current output node are defined at contact positions of the circuit under test. The two voltage sensing probes are connected in parallel and in contact with the circuit under test, and a first voltage detection node and a second voltage detection node are defined at contact positions of the circuit under test. The first voltage detection node and the second voltage detection node are between the test current input node and the test current output node. The adjustable constant current source is connected to the test current input node and the test current output node, and provides a test current in a plurality of different current values at different times to the circuit under test. The voltage measuring module is connected to the first voltage detection node and the second voltage detection node, and obtains a voltage signal between the first voltage detection node and the second voltage detection node for the test current in each of the different values. The computation unit, connected to the adjustable constant current source and the voltage measuring module, obtains the test current in each of the different values and each of the voltage signals to calculate a current change and a voltage change, calculates the impedance of the circuit under test according to the current change and the voltage change, disables the adjustable constant current source to cause the voltage measuring module to obtain the voltage signal when power is provided by a power supply in a circuit of the circuit under test, and calculates the impedance of the circuit under test according to the voltage signal and the impedance of the circuit under test.

In one embodiment, the current measuring system further includes a first high voltage protection module and a second high voltage protection module. The first high voltage module is between one of the current probes corresponding to the test current input node and the adjustable constant current source. The second high voltage protection module is between one of voltage sensing probes corresponding to the first voltage detection node and the voltage measuring module.

In one embodiment, the voltage measuring module includes a high impedance attenuation unit that performs energy attenuation on the voltage signal.

In one embodiment, the voltage measuring module includes a filter module connected to the high impedance attenuation module. The filter module includes a low-pass filter (LPF) unit, a high-pass filter (HPF) unit, an all-pass filter (APF) unit, and a switch. The switch selects one of the LPF unit, the HPF unit and the APF unit to process the voltage signal according to the type of the power supply.

In one embodiment, the voltage measuring module includes a signal buffer connected between the high impedance attenuation unit and the filter module.

In one embodiment, the voltage measuring module includes a phase rectification filter circuit connected to the filter module. The phase rectification filter circuit parses the voltage signal to obtain impedance characteristics included in the voltage signal.

In one embodiment, the voltage measuring module includes a signal amplification circuit between the filter module and the phase rectification filter circuit.

In one embodiment, the voltage measuring module includes a digital-to-analog conversion (ADC) circuit before the phase rectification filter circuit, and an analog-to-digital conversion (DAC) circuit after the phase rectification filter circuit.

Through the above technical solution, the present invention provides following features as opposed to the prior art. In the present invention, the current of the circuit under test is measured through parallel connection, and an error in a current measurement result is further reduced compared to a conventional method of measuring the current through serial connection. Further, in the present invention, the impedance of the voltage measuring module connected in parallel with the circuit under test is caused to be far greater than the impedance of the circuit under test, in a way that the equivalent impedance of the voltage measuring module and the circuit under test is extremely small, and the test current provided by the adjustable constant current source is almost limited to flow on the circuit under test. Thus, the current measuring system of the present invention is capable of accurately measuring the impedance of the circuit under test. Further, power is provided by the power supply in the circuit of the circuit under test, the voltage signal in an actual operation of the circuit under test is obtained, and the current is then calculated according to the impedance of the circuit under test and the voltage signal.

### BRIEF DESCRIPTION OF THE DRAWINGS

FIG. 1 is a flowchart of a process according to an embodiment of the present invention;

FIG. 2 is a first schematic diagram of an implementation according to an embodiment of the present invention;

FIG. 3 is a second schematic diagram of an implementation according to an embodiment of the present invention;

FIG. 4 is a function block diagram according to an embodiment of the present invention; and

FIG. 5 is a flowchart of a process according to another embodiment of the present invention.

### DETAILED DESCRIPTION OF THE PREFERRED EMBODIMENTS

Details and technical contents of the present invention are given with the accompanying drawings below.

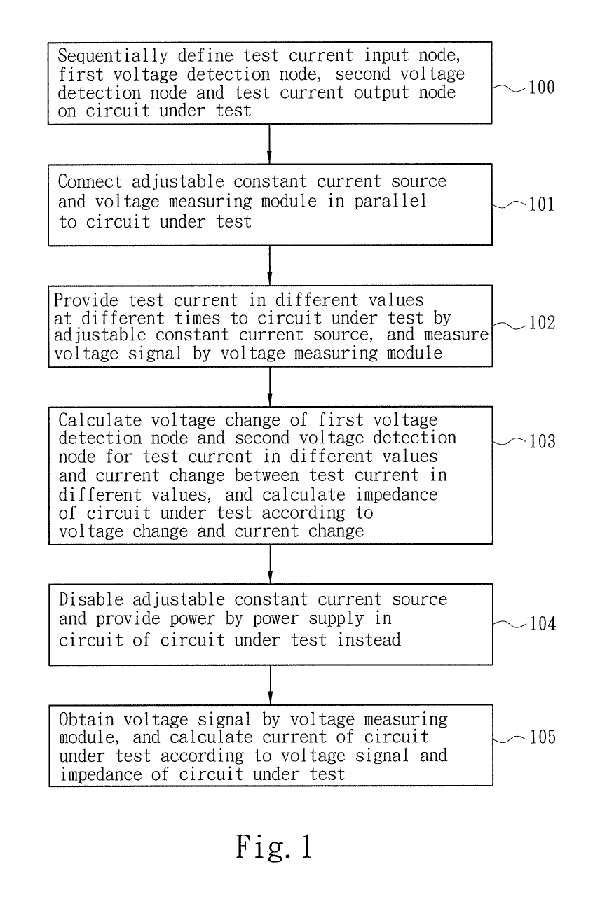

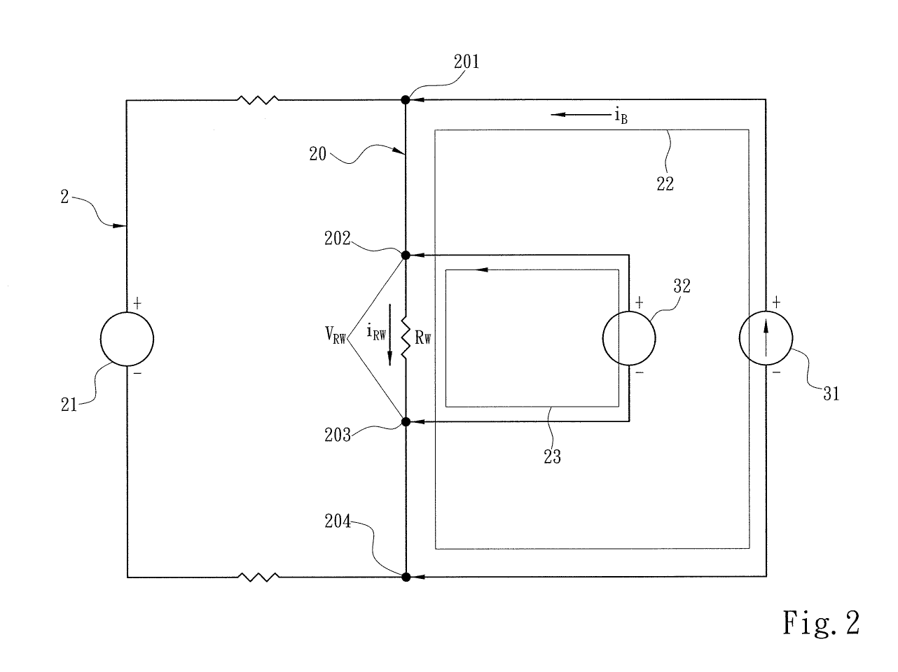

Referring to FIG. 1 and FIG. 2, the present invention provides a current measuring method including following steps. In step 1 (100), a test current input node 201, a first voltage detection node 202, a second voltage detection node 203 and a test current output node 204 are sequentially defined according to a current direction of a circuit under test 20. In step 2 (101), an adjustable constant current source 31 and a voltage measuring module 32 are connected in parallel to the circuit under test 20. Wherein, the impedance of the voltage measuring module 32 is far greater than the impedance of the circuit under test 20, the adjustable constant current source 31 is electrically connected to the test current input node 201 and the test current output node 204 to form a loop, and the voltage measuring module 32 is electrically connected to the first voltage detection node 202 and the second voltage detection node 203 to form a loop. In step 3 (102), a test current i_{B} in different current values is provided at different times to the circuit under test 20 by the adjustable constant current source 31, and a voltage signal V_{RW} between the first voltage detection node 202 and the second voltage detection node 203 is measured when the test current i_{B} of each of the different values enters the circuit under test 20. In step 4 (103), a voltage change ΔV_{RW} of the first voltage detection node 202 and the second voltage detection node 203 for the test current i_{B} in another of the different values and a current change Δi_{B} between the test current i_{B} in the different values are calculated, and the impedance R_{W} of the circuit under test 20 is calculated according to the voltage change ΔV_{RW} and the current change Δi_{B}. In step 5 (104), the adjustable constant current source 31 is disabled, and power is provided by a power supply 21 in a circuit of the under test 20 instead. In step 6 (105), the voltage signal V_{RW} between the first voltage detection node 202 and the second voltage detection node 203 is obtained by the voltage measuring module 32, and the current I_{RW} of the circuit under test 20 is calculated according to the voltage signal V_{RW} and the impedance R_{W} of the circuit under test 20.

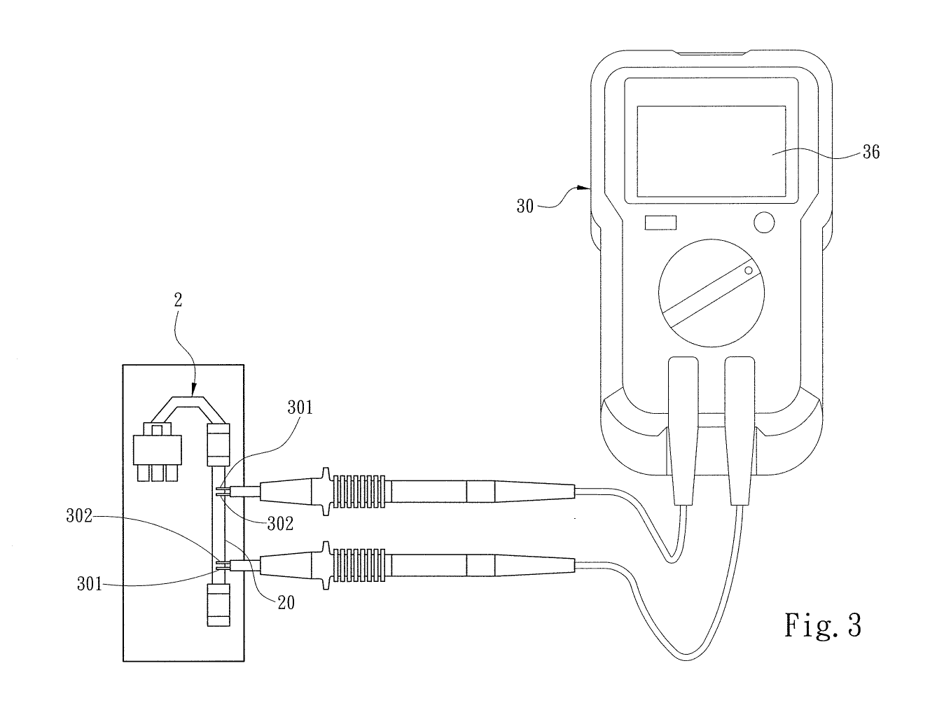

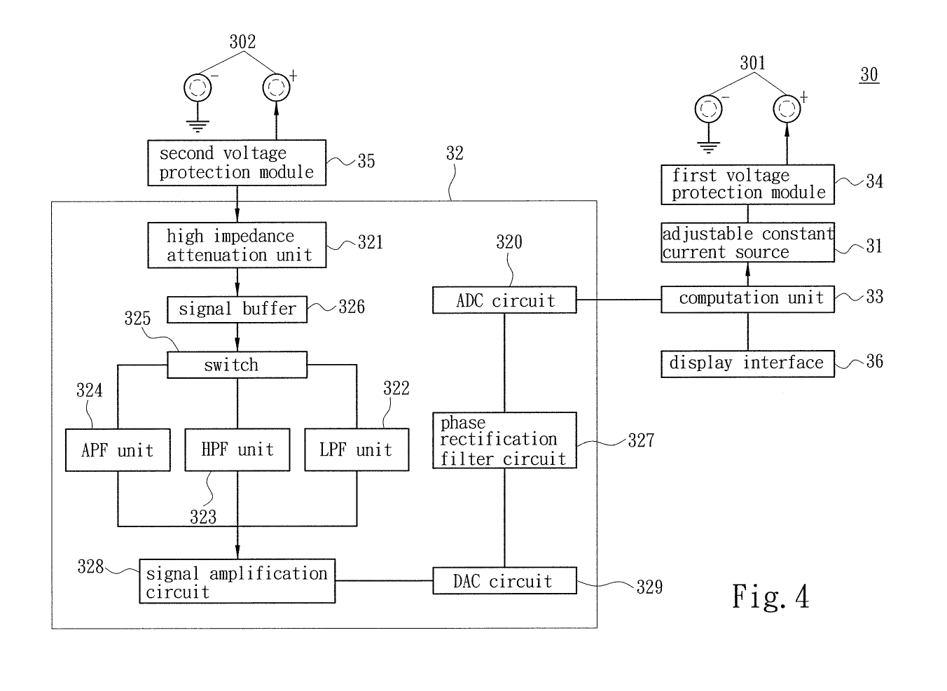

Referring to FIG. 3 and FIG. 4, the method of the present invention may be performed with the coordination of a current measuring system 30. The current measuring system 30 includes two current probes 301, two voltage sensing probes 302, the adjustable constant current source 31, the voltage measuring module 32 and a computation unit 33. The two current probes 301 are connected in parallel and in contact with the circuit under test 20, and the test current input node 201 and the test current output node 204 are defined at contact positions of the circuit under test 20. The two voltage sensing probes 302 are connected in parallel and in contact with the circuit under test 20, and the first voltage detection node 202 and the second voltage detection node 203 are defined at contact positions of the circuit under test 20. The first voltage detection node 202 and the second voltage detection node 203 are between the test current input node 201 and the test current output node 204. Further, the two current probes 301 and the two voltage sensing probes 302 are currently referred to as a four-wire probe. One of the current probes 301 corresponding to the test current input node 201 is one of the voltage sensing probes 302 corresponding to the first voltage detection node 202 are integrated onto the same rod-like structure, whereas the other two are integrated on another rod-like structure. Further, one of the two current probes 301 is a positive terminal in the implementation, and the other is a negative terminal. The same applies to the two voltage sensing probes 302.

The adjustable constant current source 31 is connected to the two current probes 301, and provides the test current I_{B} in a plurality of different current values at different times to the circuit under test 20 through the test current input node 201 and the test current output node 204. The voltage measuring module 32 is connected to the two voltage sensing probes 302, and obtains the voltage signal V_{RW} between the first voltage detection node 202 and the second voltage detection node 203 for the test current I_{B} in each of the different current values. The computation unit 33, connected to the adjustable constant current source 31 and the voltage measuring module 32, obtains the test current I_{B} in each of the different values and each corresponding voltage signal V_{RW} to calculate a current change ΔI_{B} and a voltage change V_{RW}, calculates the impedance R_{W} of the circuit under test 20 according to the current change ΔI_{B} and the voltage change V_{RW}, disables the adjustable constant current source 31 to obtain the voltage signal V_{RW} when power is provided by a power supply 21 in a circuit of the circuit under test 20, and calculates the current i_{RW} of the circuit under test 20 according to the voltage signal V_{RW} and the impedance R_{W} of the circuit under test 20. Further, the computation unit 33 may be implemented by a microprocessor, and is built-in with an algorithm mechanism through means of loading to perform associated algorithms.

At the beginning of the implementation of the present invention, in step 1 (100), a part of the circuit with a current to be measured is designated as the circuit under test 20. The so-called circuit under test 20 may be a simple wire allotted with an element. The two current probes 301 and the two voltage sensing probes 302 are sequentially connected in parallel and are in contact with the circuit under test 20, and the test current input node 201, the first voltage detection node 202, the second voltage detection node 203 and the test current output node 204 are sequentially defined based on the current direction of the circuit under test 20. In the following step 2 (101), the adjustable constant current source 31 and the voltage measuring module 32 respectively connected to the two current probes 301 and the two voltage sensing probes 302 are connected in parallel to the circuit under test 20. Further, in the present invention, the impedance of the voltage measuring module 32 connected in parallel with the circuit under test 20 is far greater than the impedance of the circuit under test 20, such that the equivalent impedance of the voltage measuring module 32 and the circuit under test 20 is extremely small. That is, when a current passes, almost all of the current passes the circuit under test 20. On the other hand, the adjustable constant current source 31, the test current input node 201, the test current output node 204 and the circuit under test 20 may form a loop (as denoted by 22 in FIG. 2); the voltage measuring module 32, the first voltage detection node 202, the second voltage detection node 203 and the circuit under test 20 form another loop (as denoted by 23 in FIG. 2). Step 3 (102) is next performed.

In step 3 (102), the computation unit 33 initially controls the adjustable constant current source 31 to output the test current i_{B} in a current value 0.1 A to the circuit under test 20, and measures the voltage signal V_{RW} between the first voltage detection node 202 and the second voltage detection node 203. The computation unit 33 then again controls the adjustable constant current source 31 to output the test current i_{B} in a current value 0.6 A to the circuit under test 20, and measures the voltage signal V_{RW} between the first voltage detection node 202 and the second voltage detection node 203. When a predetermined number of times of performing such test is complete, step 4 (103) is performed. In step 4 (103), each of the voltage signals V_{RW} and each corresponding test current i_{B} obtained are calculated to obtain the voltage change ΔV_{RW} of the first voltage detection node 202 and the second voltage detection node 203 for the test current i_{B} in the different values, and the current change A_{B} between the test current i_{B} in the different values. The impedance R_{W} of the circuit under test 20 is calculated according to the voltage change ΔV_{RW} and the current change Δ_{B}, with associated calculation details obtained based on the Ohm's law that shall be omitted herein. Further, the current values of the test current i_{B} are examples for illustration purposes, and are not to be construed as limitations to the present invention.

Next, the adjustable constant current source 31 is disabled to cause it to stop outputting the test current i_{B}, and power is provided to the circuit under test 20 alternatively by the power supply 21 in the circuit 2 of the circuit under test 20. Step 6 (105) is then performed, in which the voltage measuring module 32 obtains the voltage signal V_{RW} between the first voltage detection node 202 and the second voltage detection node 203, and the current i_{RW} of the circuit under test 20 is calculated according to the test current i_{B} currently obtained and the impedance R_{W} of the circuit under test 20.

To prevent the high voltage outputted by the power supply 21 of the circuit 2 in the circuit under test 20 from rushing into the current measuring system 30 and further from causing damages of the current measuring system 30, in one embodiment, the current measuring system 30 further includes a first high voltage protection module 34 and a second high voltage protection module 35. The first high voltage protection module 34 is located between one of the current probes 301 corresponding to the test current input node 201 and the adjustable constant current source 31. The second high voltage protection module 35 is located between one of the voltage sensing probes 302 corresponding to the first voltage detection node 202 and the voltage measuring module 32.

Further, to allow the voltage signal V_{RW} measured to be properly used by the computation unit 33, in one embodiment, the voltage measuring module 32 includes a high impedance attenuation unit 321 that performs energy attenuation on the voltage signal V_{RW}. The voltage measuring module 32 further includes a filter module connected to the high impedance attenuation unit 321. The filter module includes a low-pass filter (LPF) unit 322, a high-pass filter (HPF) unit 323, an all-pass filter (APF) unit 324, and a switch 325. The switch 325 selects one of the LPF unit 322, the HPF unit 323 and the APF unit 324 to process the voltage signal V_{RW} according to the type of the power supply 21. On the other hand, in the present invention, step 6 (105) further includes sub-step 106. In sub-step 106, the LPF unit 322 or the HPF unit 323 is selected to process the voltage signal V_{RW} according to the type of the power supply 21. More specifically, the voltage signal V_{RW} is processed by the LPF unit 322 when the power supply 21 is a direct-current (DC) source, and is processed by the HPF unit 323 when the power supply 21 is an alternating-current (AC) source.

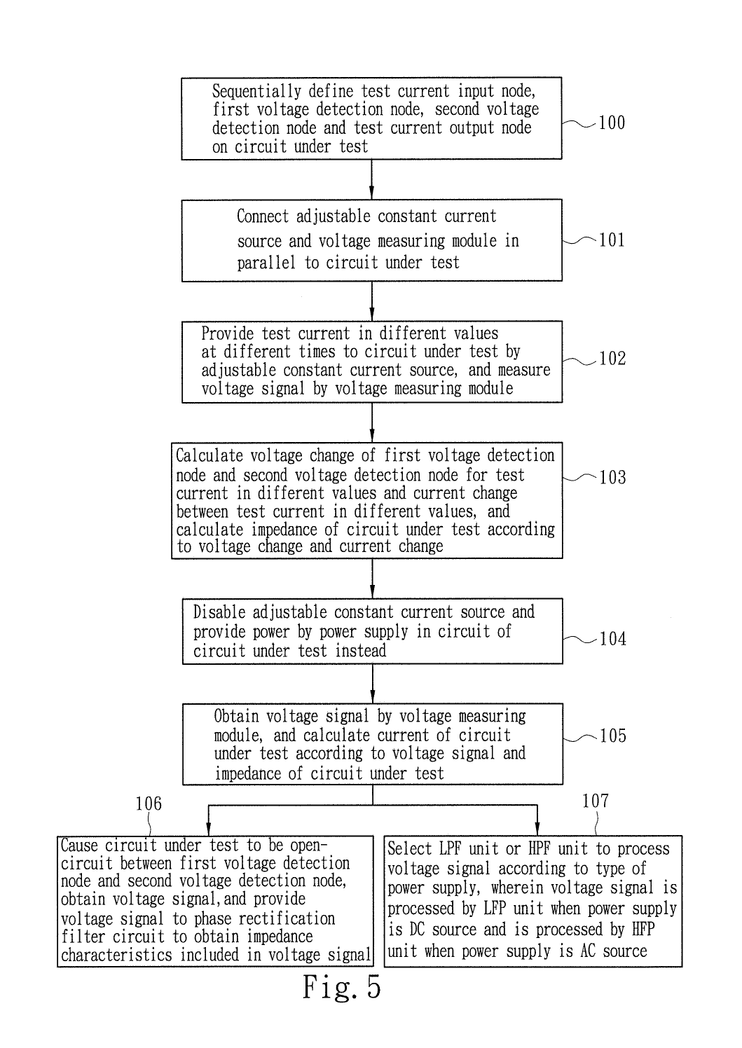

Referring to FIG. 5, in one embodiment, the voltage measuring module 32 includes a signal buffer 326 connected between the high impedance attenuation unit 321 and the filter module, and a phase rectification filter circuit 327 connected to the filter module. The phase rectification filter circuit 327 parses the voltage signal V_{RW} to obtain the impedance characteristics included in the voltage signal V_{RW}. In the present invention, step 6 (105) further includes another sub-step 107. In sub-step 107, the circuit under test 20 is caused to be open-circuit between the first voltage detection node 202 and the second voltage detection node 203, the voltage signal V_{RW} between the first voltage detection node 202 and the second voltage detection node 203 is obtained, and the voltage signal V_{RW} is provided to a phase rectification filter circuit to obtain the impedance characteristics included in the voltage signal V_{RW}. Further, the so-called impedance characteristics are resistance characteristics, inductance characteristics and capacitance characteristics generally known in the technical field.

In one embodiment, the voltage measuring module 32 includes a signal amplification circuit 328 disposed between the filter module and the phase rectification filter circuit 327. On the other hand, the voltage measuring module 32 may further include a digital-to-analog conversion (DAC) circuit 329 disposed before the phase rectification filter circuit 327, and an analog-to-digital conversion (ADC) circuit 320 disposed after the phase rectification filter circuit 327. In addition, the current measuring system 30 may further include a display interface 36 for displaying a detected result.

1. A current measuring method, comprising steps of:
step 1: sequentially defining a test current input node, a first voltage detection node, a second voltage detection node and a test current output node according to a current direction of a circuit under test;
step 2: connecting an adjustable constant current source and a voltage measuring module in parallel to the circuit under test, wherein the impedance of the voltage measuring module is far greater than the impedance of the circuit under test, the adjustable constant current source is electrically connected to the test current input node and the test current output node to form a loop, and the voltage measuring module is electrically connected to the first voltage detection node and the second voltage detection node to form a loop;
step 3: providing test currents in different current values at different times to the circuit under test by the adjustable constant current source, and measuring voltage signals between the first voltage detection node and the second voltage detection node by the voltage measuring module when each of the test currents in different current values enters the circuit under test;
step 4: obtaining the test currents and the voltage signals by a computation unit to calculate a voltage change of the first voltage detection node and the second voltage detection node for the test current in the different current values, and a current change between the test current in the different values, and calculating the impedance of the circuit under test according to the voltage change and the current change;
step 5: disabling the adjustable constant current source, and providing power by a power supply in a circuit of the circuit under test; and
step 6: obtaining a voltage signal between the first voltage detection node and the second voltage detection node by the voltage measuring module from step 5, wherein the voltage signal is attenuated by a high impedance attenuation unit, selecting a low-pass filter (LPF) unit or a high-pass filter (HPF) unit by a switch that is controlled by the computation unit to process the voltage signal according to the type of the power supply unit, wherein the voltage signal is processed by the LPF unit when the power supply is a direct-current (DC) source and is processed by the HPF unit when the power supply is an alternating-current (AC) source, and calculating a current of the circuit under test according to the voltage signal and the impedance of the circuit under test by the computation unit.

2. The current measuring method of claim 1, wherein step 6 further comprises a sub-step of:
causing the circuit under test to be open-circuit between the first voltage detection node and the second voltage detection node, obtaining the voltage signal between the first voltage detection node and the second voltage detection node, providing the voltage signal to a phase rectification filter circuit to obtain impedance characteristics included in the voltage signal.

3. (canceled)

4. A current measuring system, comprising:
two current probes, connected in parallel and in contact with a circuit under test, a test current input node and a test current output node defined at contact positions of the circuit under test;
two voltage sensing probes, connected in parallel and in contact with the circuit under test, a first voltage detection node and a second detection node defined at contact positions of the circuit under test, the first voltage detection node and the second voltage detection node located between the test current input node and the test current output node;
an adjustable constant current source, connected to the test current input node and the test current output node, providing test currents in different current values at different times to the circuit under test;
a voltage measuring module, connected to the first voltage detection node and the second voltage detection node, obtaining voltage signals between the first voltage detection node and the second voltage detection node, each of the voltage signals is corresponding to each of the test currents in different current values, comprising a high impedance attenuation unit that performs energy attenuation on the voltage signal, wherein the voltage measuring module comprises a filter module connected to the high impedance attenuation unit, the filter module comprises a low-pass filter (LPF) unit, a high-pass filter (HPF) unit, an all-pass filter (APF) unit, and a switch that is controlled by the computation unit to select one of the LPF unit, the HPF unit and the APF unit to process the voltage signal according to the type of the power supply;
a computation unit, connected to the adjustable constant current source and the voltage measuring module, obtaining the test current in each of the different current values and each corresponding voltage signal to calculate a current change and a voltage change, calculating impedance of the circuit under test according to the voltage change and the current change, disabling the adjustable constant current source and causing the voltage measuring module to obtain power from a power supply in a circuit of the circuit under test, and calculating a current of the circuit under test according to the voltage signal and the impedance of the circuit under test;
a high voltage protection module, located between one of the current probes corresponding to the test current input node and the adjustable constant current source; and
a second high voltage protection module, located between one of the voltage sensing probes corresponding to the first voltage detection node and the voltage measuring module.

5. (canceled)

6. (canceled)

7. (canceled)

8. The current measuring system of claim 4, wherein the voltage measuring module comprises a signal buffer connected between the high impedance attenuation unit and the filter module.

9. The current measuring system of claim 4, wherein the voltage measuring module comprises a phase rectification filter circuit, which is connected to the filter module and parses the voltage signal to obtain impedance characteristics included in the voltage signal.

10. The current measuring system of claim 9, wherein the voltage measuring module comprises a signal amplification circuit disposed between the filter module and the phase rectification filter circuit.

11. The current measuring system of claim 9, wherein the voltage measuring module comprises a digital-to-analog (DAC) conversion circuit disposed before the phase rectification filter circuit and an analog-to-digital (ADC) conversion circuit disposed after the phase rectification filter circuit.
